(19) United States
(12) Patent Application Publication
(10) Pub. No.: US 2024/0421145 A1
(43) Pub. Date: Dec. 19, 2024

(54) CIRCUIT LAYOUTS WITH STAGGERED GATE AND SOURCE/DRAIN REGIONS

(71) Applicant: International Business Machines Corporation, Armonk, NY (US)

(72) Inventors: Carl Radens, LaGrangeville, NY (US); Brent A. Anderson, Jericho, VT (US); Albert M. Chu, Nashua, NH (US); Ruilong Xie, Niskayuna, NY (US)

(21) Appl. No.: 18/333,953

(22) Filed: Jun. 13, 2023

(51) Int. Cl. H01L 27/02; H10B 10/00

(52) U.S. Cl. CPC H01L 27/0207; H10B 10/12

(57) ABSTRACT

A semiconductor structure includes a first circuit row including one or more first circuit cells and a second circuit row including one or more second circuit cells. At a cell boundary between the one or more first circuit cells in the first circuit row and the one or more second circuit cells in the second circuit row, one or more first gate regions of the one or more first circuit cells in the first circuit row are staggered with one or more second gate regions of the one or more second circuit cells in the second circuit row.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments of the invention provide techniques for forming circuit layouts with staggered gate and source/drain regions.

In one embodiment, a semiconductor structure includes a first circuit row including one or more first circuit cells and a second circuit row including one or more second circuit cells. At a cell boundary between the one or more first circuit cells in the first circuit row and the one or more second circuit cells in the second circuit row, one or more first gate regions of the one or more first circuit cells in the first circuit row are staggered with one or more second gate regions of the one or more second circuit cells in the second circuit row.

In another embodiment, a semiconductor structure includes an array of circuit cells arranged in a first row and at least a second row. Gate regions and source/drain regions of the array of circuit cells are staggered at a cell boundary of the first row and the second row.

In another embodiment, an integrated circuit includes an array of circuit cells arranged in a first row and at least a second row. Gate regions and source/drain regions of the array of circuit cells are staggered at a cell boundary of the first row and the second row.

These and other features and advantages of embodiments described herein will become more apparent from the accompanying drawings and the following detailed description.

### BRIEF DESCRIPTION OF THE DRAWINGS

FIGS. 1A and 1B show views of a circuit layout structure with and without staggered gate and source/drain regions, according to an embodiment of the invention.

FIG. 2 shows a circuit layout structure with staggered gate and source/drain regions, according to an embodiment of the invention.

FIG. 3 shows a circuit layout structure with gate strap regions connecting staggered gate regions, according to an embodiment of the invention.

FIG. 4 shows a circuit layout structure with gate network layers connecting staggered gate regions, according to an embodiment of the invention.

FIG. 5 shows a circuit layout structure with staggered gate and source/drain regions with frontside source/drain regions pulled back, according to an embodiment of the invention.

FIG. 6 shows a circuit layout structure with staggered gate and source/drain regions with a notch in an active region, according to an embodiment of the invention.

FIG. 7 shows an integrated circuit including a circuit array with staggered gate and source/drain regions, according to an embodiment of the invention.

### DETAILED DESCRIPTION

Illustrative embodiments of the invention may be described herein in the context of illustrative methods for forming circuit layouts with staggered gate and source/drain regions, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

With continuous scaling, more and more devices (e.g., transistors) are packed into integrated circuit chips (e.g., into one or more 100 millimeter (mm)² chips). To provide desired functionality, the devices must be interconnected through wiring and routing. With an increased number of devices in an integrated circuit, more and more wiring and routing resources are required to precisely connect the integrated circuit as desired for a particular use case. Thus, for example, more and more metal layers may be needed to connect all of the devices in an integrated circuit.

A circuit layout may include one or more circuit rows, with each circuit row including one or more circuit cells. Illustrative embodiments provide circuit layouts which allow for reduced cell boundary spacing between circuit cells in adjacent circuit rows through providing an array of circuit cells with staggered gate and source/drain regions (e.g., at cell boundaries). Structures at the array boundary may include device channel and source/drain regions with a staggered gate electrode pattern. The circuit layout may include staggered gate electrodes at the cell boundary. In some embodiments, the circuit layout includes one or more static random-access memory (SRAM) cells with staggered gate electrodes at the cell boundary. The circuit layout may include gate contacts to individual devices, with a shared gate network (e.g., using gate strap structures or other network layers or interconnecting structures). Contacts to the gate regions may be from above, or from the backside. There may be structures at the intersection of device regions with a common gate electrode network. The circuit cells in the array may be field-effect transistors (FETs) of various different types, including but not limited to planar FETs, fin-type FETs (FinFETs), nanosheet FETs, nanowire FETs, stacked FETs, etc.

A process flow for forming circuit layouts with staggered gate and source/drain regions at a cell boundary may include forming transistors and dummy gates with a hard mark, then patterning first regions for first gates (e.g., in a top or first row) followed by oxide fill and chemical mechanical planarization (CMP). Next, second regions for second gates (e.g., in a bottom or second row) are then patterned, followed by masking and trimming the gate pattern for the second gates. The gate pattern is the transferred into the hard mask, and etched to form the dummy gates.

Circuit layouts with staggered gate and source/drain regions at a cell boundary advantageously provide a significant reduction in cell boundary spacing (e.g., an approximate 0.54× compaction of nFET-to-nFET spacing). For a six transistor (6T) SRAM structure, a significant overall memory cell area reduction of approximately 10% may be achieved using the circuit layouts described herein with staggered gate and source/drain regions at the cell boundary. Further, the staggered gate and source/drain arrangement allows for greater freedom in device-to-device placement proximity (e.g., elimination of gate region tip-to-tip distance for gate regions in adjacent circuit rows, as well as elimination of one out of two “gate-past-active region” spacing constraints).

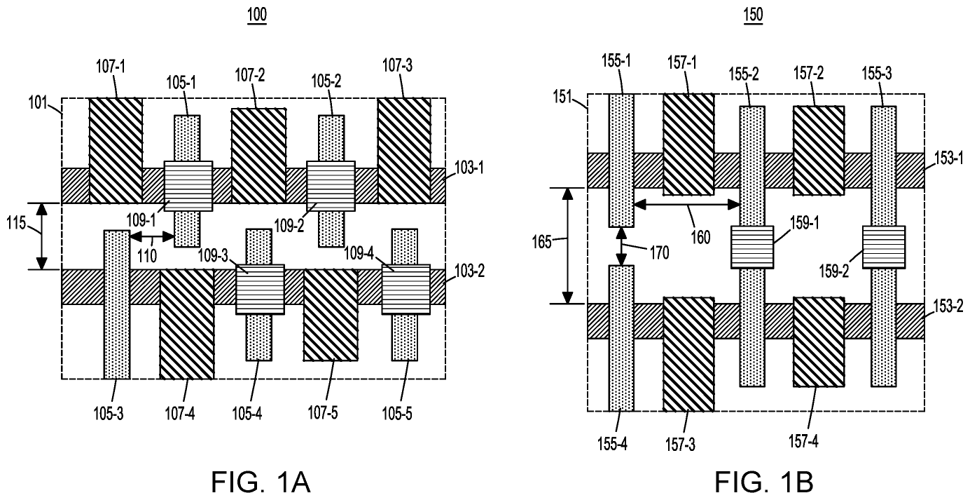

FIG. 1A shows a top-down view 100 of a circuit layout 101 including active regions 103-1 and 103-2 (collectively, active regions 103), gate regions 105-1, 105-2, 105-3, 105-4 and 105-5 (collectively, gate regions 105), source/drain regions 107-1, 107-2, 107-3, 107-4 and 107-5 (collectively, source/drain regions 107), and gate contacts 109-1, 109-2, 109-3 and 109-4 (collectively, gate contacts 109). As illustrated, the gate regions 105-1 and 105-2 in the “top” row are staggered relative to the gate regions 105-3, 105-4 and 105-5 in the “bottom” row, represented by offset distance 110. There is similar staggering between the source/drain regions 107-1, 107-2 and 107-3 in the top row relative to the source/drain regions 107-4 and 107-5 in the bottom row. This staggering advantageously reduces the cell boundary requirement, represented by distance 115.

For comparison, FIG. 1B shows a top-down view 150 of a circuit layout 151 including active regions 153-1 and 153-2 (collectively, active regions 153), gate regions 155-1, 155-2, 155-3 and 155-4 (collectively, gate regions 155), source/drain regions 157-1, 157-2, 157-3 and 157-4 (collectively, source/drain regions 157), and gate contacts 159-1 and 159-2 (collectively, gate contacts 159). In the circuit layout 151, there is no staggering of the gate regions 155 and the source/drain regions 157. Thus, there is an increased distance 160 between adjacent gate regions 155-1 and 155-2 (relative to offset distance 110). Further, the cell boundary requirement, represented by distance 165, is increased (relative to distance 115). This is a result of minimum “tip-to-top” spacing 170 between the gate regions 155-1 and 155-4 in the top and bottom rows which are aligned with one another. The staggered arrangement of the gate regions 105 in the circuit layout 101 eliminates the need for such tip-to-tip spacing, as the gate regions 105 are offset from one another.

It should be noted that the pitch (e.g., left to right) spacing is the same in both the circuit layouts 101 and 151. The top-to-bottom spacing between adjacent circuit rows, however, is made smaller utilizing the staggered gate and source/drain region arrangement. The staggered gate and source/drain region arrangement shown in circuit layout 101 eliminates tip-to-tip spacing issues (e.g., which can be a critical limiting factor in reducing the circuit area), and also facilitates formation of gate contacts to individual devices. As shown in the circuit layout 101, there are individual gate contacts 109 to each of the gate regions 105. This is compared with the circuit layout 151, in which the gate contacts 159 are shared for the gate regions 155 in the top and bottom circuit rows.

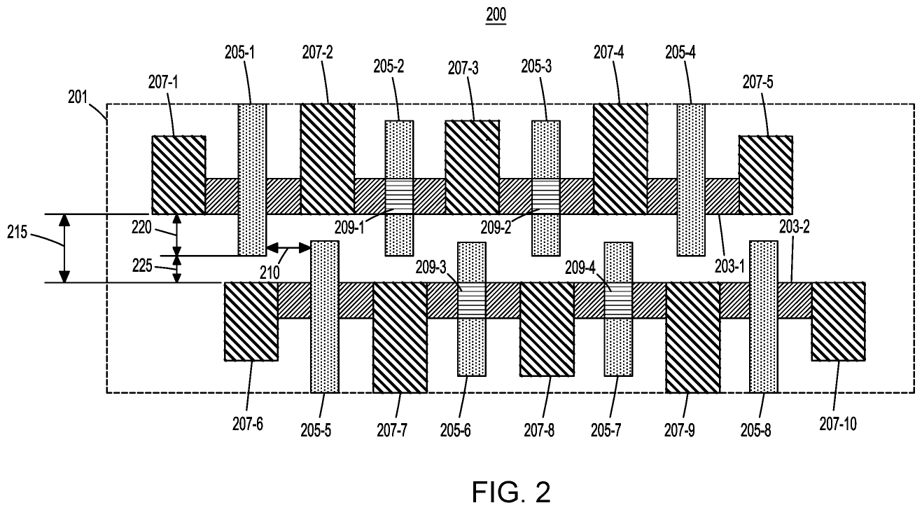

FIG. 2 shows a top-down view 200 of a circuit layout 201 including active regions 203-1 and 203-2 (collectively, active regions 203), gate regions 205-1, 205-2, 205-3, 205-4, 205-5, 205-6, 205-7 and 205-8 (collectively, gate regions 205), source/drain regions 207-1, 207-2, 207-3, 207-4, 207-5, 207-6, 207-8, 207-9 and 207-10 (collectively, source/drain region 207), and gate contacts 209-1, 209-2, 209-3 and 209-4 (collectively, gate contacts 209). The offset between adjacent ones of the gate regions 205 is denoted by offset distance 210, the cell boundary spacing is denoted by distance 215, the gate-to-active region spacing is denoted by distance 220, and the gate-past-active region spacing is denoted by distance 225. The circuit layout 201 may be used for an SRAM structure and illustrates n-to-n spacing. Here, the gate contacts 209 may be wordline (WL) contacts in a gate contact over active region (CBoA) arrangement. The cell boundary spacing distance 215 is the n-to-n spacing, and may be approximately 23.5 nm (as compared to a non-staggered layout which may have 43 nm n-to-n spacing, illustrating a 0.54× reducing in n-to-n space using the staggered circuit layout 201). The gate-to-active region spacing distance 220 may be approximately 10 nm, and the gate-past-active region spacing distance 225 may be approximately 13.5 nm.

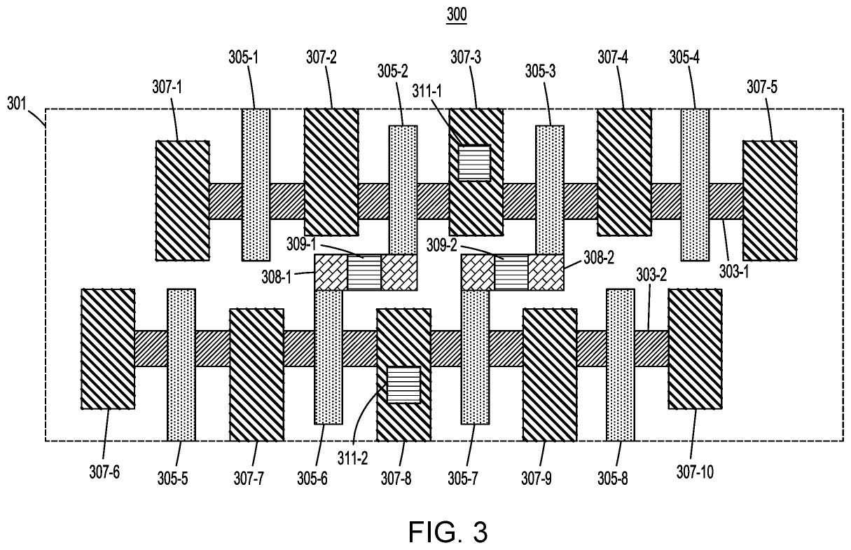

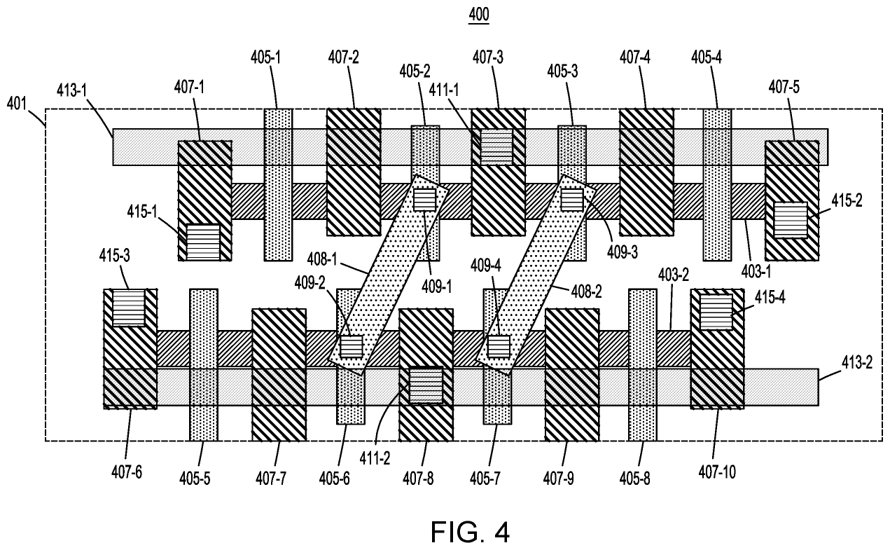

As discussed above, the novel circuit layouts described herein with staggered gate and source/drain regions facilitate formation of gate contacts to individual devices (e.g., individual ones of the gate regions). In some cases, however, it may be desired to connect two or more gate regions. FIGS. 3 and 4 illustrate two possible ways in which gate contacts to multiple gate regions in circuit layouts with staggered gate and source/drain regions may be connected with one another.

FIG. 3 shows a top-down view 300 of a circuit layout 301 including active regions 303-1 and 303-2 (collectively, active regions 303), gate regions 305-1, 305-2, 305-3, 305-4, 305-5, 305-6, 305-7 and 305-8 (collectively, gate regions 305), source/drain regions 307-1, 307-2, 307-3, 307-4, 307-5, 307-6, 307-7, 307-8, 307-9 and 307-10 (collectively, source/drain regions 307), gate strapping layers 308-1 and 308-2 (collectively, gate strapping layers 308), gate contacts 309-1 and 309-2 (collectively, gate contacts 309), and bitline (BL) contacts 311-1 and 311-2 (collectively, BL contacts 311). Here, the gate strapping layer 308-1 connects the gate regions 305-2 and 305-6 to gate contact 309-1, and the gate strapping layer 308-2 connects the gate regions 305-3 and 305-7 to the gate contact 309-2. The BL contacts 311-1 and 311-2 are formed to the source/drain regions 307-3 and 307-8, respectively.

FIG. 4 shows a top-down view 400 of a circuit layout 401 including active regions 403-1 and 403-2 (collectively, active regions 403), gate regions 405-1, 405-2, 405-3, 405-4, 405-5, 405-6, 405-7 and 405-8 (collectively, gate regions 405), source/drain regions 407-1, 407-2, 407-3, 407-4, 407-5, 407-6, 407-7, 407-8, 407-9 and 407-10 (collectively, source/drain regions 407), gate network layers 408-1 and 408-2 (collectively, gate network layers 408), gate contacts 409-1, 409-2, 409-3 and 409-4 (collectively, gate contacts 409), BL contacts 411-1 and 411-2 (collectively, BL contacts 411), BL network layers 413-1 and 413-2 (collectively, BL network layers 413), and source/drain contacts 415-1, 415-2, 415-3 and 415-4 (collectively, source/drain contacts 415). Here, the gate contacts 409 are formed over portions of the active regions 403 in a CBoA arrangement, with the gate network layer 408-1 connecting gate contacts 409-1 and 409-2 and the gate network layer 408-2 connecting gate contacts 409-3 and 409-4. It should be noted that the gate contacts 409 and gate network layers 408 may be formed on the frontside or the backside of the structure, to form frontside or backside gate contact structures as desired. The BL network layers 413 connect to the BL contacts 411.

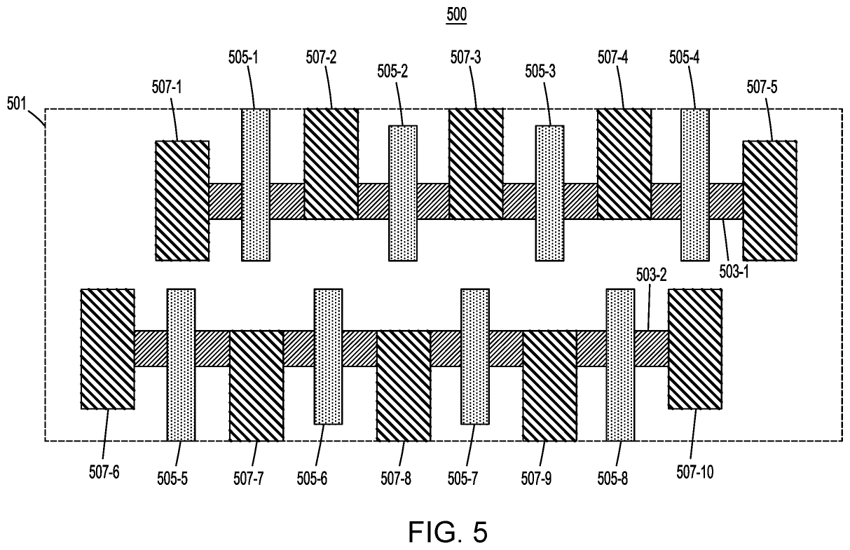

FIG. 5 shows a top-down view 500 of a circuit layout 501 including active regions 503-1 and 503-2 (collectively, active regions 503), gate regions 505-1, 505-2, 505-3, 505-4, 505-5, 505-6, 505-7 and 505-8 (collectively, gate regions 505), and source/drain regions 507-1, 507-2, 507-3, 507-4, 507-5, 507-6, 507-7, 507-8, 507-9 and 507-10 (collectively, source/drain regions 510). Although not shown in FIG. 5, various gate contacts may be formed to the gate regions 505. The gate contacts may use individual device contacts (e.g., using the gate contacts 209), strapped gate contacts (e.g., using the gate strapping layers 308 and the gate contacts 309), gate contacts interconnected with network layers (e.g., using the gate network layers 408 and the gate contacts 409), etc. FIG. 5 shows an arrangement in which frontside ones of the source/drain regions 507 (e.g., source/drain regions 507-2, 507-3, 507-4, 507-7, 507-8 and 507-9) are pulled back to the boundary of the active regions 503.

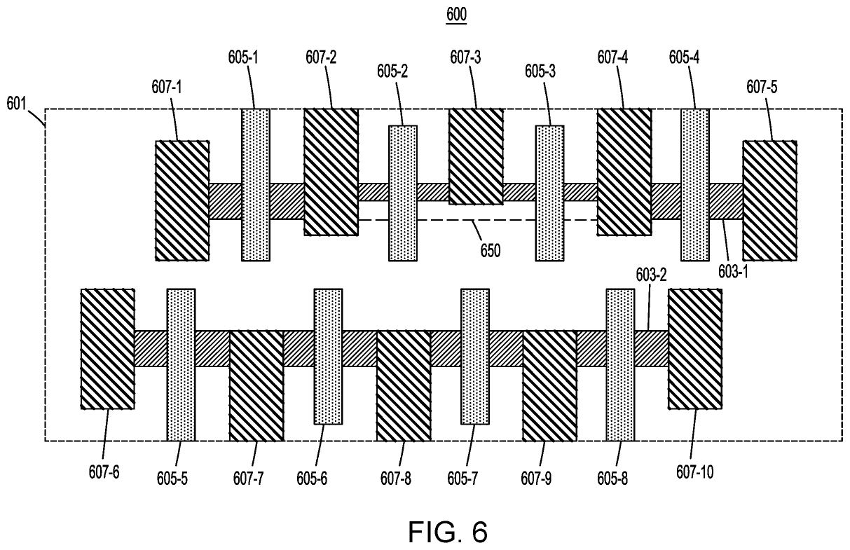

FIG. 6 shows a top-down view 600 of a circuit layout 601 including active regions 603-1 and 603-2 (collectively, active regions 603), gate regions 605-1, 605-2, 605-3, 605-4, 605-5, 605-6, 605-7 and 605-8 (collectively, gate regions 605), and source/drain regions 607-1, 607-2, 607-3, 607-4, 607-5, 607-6, 607-7, 607-8, 607-9 and 607-10 (collectively, source/drain regions 610). Although not shown in FIG. 6, various gate contacts may be formed to the gate regions 605. The gate contacts may use individual device contacts (e.g., using the gate contacts 209), strapped gate contacts (e.g., using the gate strapping layers 308 and the gate contacts 309), gate contacts interconnected with network layers (e.g., using the gate network layers 408 and the gate contacts 409), etc. FIG. 6 shows an arrangement in which a notch 650 is formed in one of the active regions 603-1, and where some of the source/drain regions 607 (e.g., source/drain regions 607-2, 607-3, 607-4, 607-7, 607-8 and 607-9) are pulled back to the boundary of the active regions 603. In the area of the notch 650, the source/drain region 607-3 is pulled back to the boundary of the notch 650.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, complementary metal-oxide-semiconductors (CMOSs), metal-oxide-semiconductor field-effect transistors (MOSFETs), and/or FinFETs. By way of non-limiting example, the semiconductor devices can include, but are not limited to CMOS, MOSFET, and FinFET devices, and/or semiconductor devices that use CMOS, MOSFET, and/or FinFET technology.

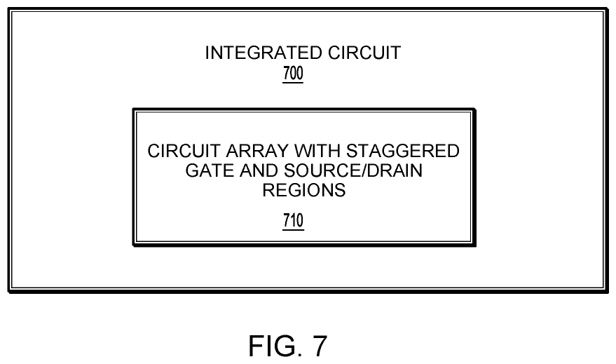

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor. FIG. 7 shows an example integrated circuit 700 which includes a circuit array 710 with staggered gate and source/drain regions.

In some embodiments, a semiconductor structure includes a first circuit row including one or more first circuit cells and a second circuit row including one or more second circuit cells. At a cell boundary between the one or more first circuit cells in the first circuit row and the one or more second circuit cells in the second circuit row, one or more first gate regions of the one or more first circuit cells in the first circuit row are staggered with one or more second gate regions of the one or more second circuit cells in the second circuit row.

At the cell boundary between the one or more first circuit cells in the first circuit row and the one or more second circuit cells in the second circuit row, one or more first source/drain regions of the one or more first circuit cells in the first circuit row may be staggered with one or more second source/drain regions of the one or more second circuit cells in the second circuit row.

At the cell boundary between the one or more first circuit cells in the first circuit row and the one or more second circuit cells in the second circuit row, at least one of the one or more first gate regions of the one or more first circuit cells in the first circuit row may be aligned with at least one of the one or more second source/drain regions of the one or more second circuit cells in the second circuit row.

At the cell boundary between the one or more first circuit cells in the first circuit row and the one or more second circuit cells in the second circuit row, at least one of the one or more second gate regions of the one or more second circuit cells in the second circuit row may be aligned with at least one of the one or more first source/drain regions of the one or more first circuit cells in the first circuit row.

The semiconductor structure may further include individual gate contacts to at least one of the one or more first gate regions of the one or more first circuit cells in the first circuit row and at least one of the one or more second gate regions of the one or more second circuit cells in the second circuit row.

The semiconductor structure may further include a first gate contact to a first one of the one or more first gate regions of a first one of the one or more first circuit cells in the first circuit row, a second gate contact to a first one of the one or more second gate regions of a first one of the one or more second circuit cells in the second circuit row, and a gate connection layer connecting the first gate contact and the second gate contact. The first gate contact, the second gate contact and the gate connection layer may be formed at the cell boundary between the one or more first circuit cells in the first circuit row and the one or more second circuit cells in the second circuit row. The first gate contact may be formed over a first active region of the first circuit row, the second gate contact may be formed over a second active region of the second circuit row, and the gate connection layer may extend from the first active region of the first circuit row and across the cell boundary between the one or more first circuit cells in the first circuit row and the one or more second circuit cells in the second circuit row to the second active region of the second circuit row.

The semiconductor structure may further include one or more gate contacts to at least one of the one or more first gate regions and the one or more second gate regions from a frontside of the semiconductor structure.

The semiconductor structure may further include one or more gate contacts to at least one of the one or more first gate regions and the one or more second gate regions from a backside of the semiconductor structure.

The one or more first circuit cells and the one or more second circuit cells may be transistors of a static random-access memory cell.

At least one of the one or more first circuit cells and the one or more second circuit cells may be at least one of a planar transistor, a fin-type field-effect transistor, a nanosheet transistor, a nanowire transistor and a stacked field-effect transistor.

In some embodiments, a semiconductor structure includes an array of circuit cells arranged in a first row and at least a second row. Gate regions and source/drain regions of the array of circuit cells are staggered at a cell boundary of the first row and the second row.

The semiconductor structure may further include individual gate contacts to at least one of the gate regions in the first row of the array of circuit cells and at least one of the gate regions in the second row of the array of circuit cells.

The semiconductor structure may further include a first gate contact to at least one of the gate regions in the first row of the array of circuit cells, a second gate contact to at least one of the gate regions in the second row of the array of circuit cells, and a gate connection layer connecting the first gate contact and the second gate contact, wherein the first gate contact, the second gate contact and the gate connection layer are formed at the cell boundary of the first row and the second row.

The semiconductor structure may further include a first gate contact to at least one of the gate regions in the first row of the array of circuit cells, a second gate contact to at least one of the gate regions in the second row of the array of circuit cells, and a gate connection layer connecting the first gate contact and the second gate contact, wherein the first gate contact is formed over a first active region of the first row, wherein the second gate contact is formed over a second active region of the second row, and wherein the gate connection layer extends from the first active region of the first row and across the cell boundary to the second active region of the second row.

In some embodiments, an integrated circuit includes an array of circuit cells arranged in a first row and at least a second row. Gate regions and source/drain regions of the array of circuit cells are staggered at a cell boundary of the first row and the second row.

The integrated circuit may further include individual gate contacts to at least one of the gate regions in the first row of the array of circuit cells and at least one of the gate regions in the second row of the array of circuit cells.

The integrated circuit may further include a first gate contact to at least one of the gate regions in the first row of the array of circuit cells, a second gate contact to at least one of the gate regions in the second row of the array of circuit cells, and a gate connection layer connecting the first gate contact and the second gate contact, wherein the first gate contact, the second gate contact and the gate connection layer are formed at the cell boundary of the first row and the second row.

The integrated circuit may further include a first gate contact to at least one of the gate regions in the first row of the array of circuit cells, a second gate contact to at least one of the gate regions in the second row of the array of circuit cells, and a gate connection layer connecting the first gate contact and the second gate contact, wherein the first gate contact is formed over a first active region of the first row, wherein the second gate contact is formed over a second active region of the second row, and wherein the gate connection layer extends from the first active region of the first row and across the cell boundary to the second active region of the second row.

It should be understood that the various layers, structures, and regions shown in the figures are schematic illustrations that are not drawn to scale. In addition, for case of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure comprising:
a first circuit row comprising one or more first circuit cells; and
a second circuit row comprising one or more second circuit cells;
wherein at a cell boundary between the one or more first circuit cells in the first circuit row and the one or more second circuit cells in the second circuit row, one or more first gate regions of the one or more first circuit cells in the first circuit row are staggered with one or more second gate regions of the one or more second circuit cells in the second circuit row.

2. The semiconductor structure of claim 1, wherein at the cell boundary between the one or more first circuit cells in the first circuit row and the one or more second circuit cells in the second circuit row, one or more first source/drain regions of the one or more first circuit cells in the first circuit row are staggered with one or more second source/drain regions of the one or more second circuit cells in the second circuit row.

3. The semiconductor structure of claim 2, wherein at the cell boundary between the one or more first circuit cells in the first circuit row and the one or more second circuit cells in the second circuit row, at least one of the one or more first gate regions of the one or more first circuit cells in the first circuit row is aligned with at least one of the one or more second source/drain regions of the one or more second circuit cells in the second circuit row.

4. The semiconductor structure of claim 3, wherein at the cell boundary between the one or more first circuit cells in the first circuit row and the one or more second circuit cells in the second circuit row, at least one of the one or more second gate regions of the one or more second circuit cells in the second circuit row is aligned with at least one of the one or more first source/drain regions of the one or more first circuit cells in the first circuit row.

5. The semiconductor structure of claim 1, further comprising individual gate contacts to at least one of the one or more first gate regions of the one or more first circuit cells in the first circuit row and at least one of the one or more second gate regions of the one or more second circuit cells in the second circuit row.

6. The semiconductor structure of claim 1, further comprising:
a first gate contact to a first one of the one or more first gate regions of a first one of the one or more first circuit cells in the first circuit row;
a second gate contact to a first one of the one or more second gate regions of a first one of the one or more second circuit cells in the second circuit row; and
a gate connection layer connecting the first gate contact and the second gate contact.

7. The semiconductor structure of claim 6, wherein the first gate contact, the second gate contact and the gate connection layer are formed at the cell boundary between the one or more first circuit cells in the first circuit row and the one or more second circuit cells in the second circuit row.

8. The semiconductor structure of claim 6, wherein the first gate contact is formed over a first active region of the first circuit row, the second gate contact is formed over a second active region of the second circuit row, and the gate connection layer extends from the first active region of the first circuit row and across the cell boundary between the one or more first circuit cells in the first circuit row and the one or more second circuit cells in the second circuit row to the second active region of the second circuit row.

9. The semiconductor structure of claim 1, further comprising one or more gate contacts to at least one of the one or more first gate regions and the one or more second gate regions from a frontside of the semiconductor structure.

10. The semiconductor structure of claim 1, further comprising one or more gate contacts to at least one of the one or more first gate regions and the one or more second gate regions from a backside of the semiconductor structure.

11. The semiconductor structure of claim 1, wherein the one or more first circuit cells and the one or more second circuit cells comprise transistors of a static random-access memory cell.

12. The semiconductor structure of claim 1, wherein at least one of the one or more first circuit cells and the one or more second circuit cells comprise at least one of a planar transistor, a fin-type field-effect transistor, a nanosheet transistor, a nanowire transistor and a stacked field-effect transistor.

13. A semiconductor structure comprising:
an array of circuit cells arranged in a first row and at least a second row;
wherein gate regions and source/drain regions of the array of circuit cells are staggered at a cell boundary of the first row and the second row.

14. The semiconductor structure of claim 13, further comprising individual gate contacts to at least one of the gate regions in the first row of the array of circuit cells and at least one of the gate regions in the second row of the array of circuit cells.

15. The semiconductor structure of claim 13, further comprising a first gate contact to at least one of the gate regions in the first row of the array of circuit cells, a second gate contact to at least one of the gate regions in the second row of the array of circuit cells, and a gate connection layer connecting the first gate contact and the second gate contact, wherein the first gate contact, the second gate contact and the gate connection layer are formed at the cell boundary of the first row and the second row.

16. The semiconductor structure of claim 13, further comprising a first gate contact to at least one of the gate regions in the first row of the array of circuit cells, a second gate contact to at least one of the gate regions in the second row of the array of circuit cells, and a gate connection layer connecting the first gate contact and the second gate contact, wherein the first gate contact is formed over a first active region of the first row, wherein the second gate contact is formed over a second active region of the second row, and wherein the gate connection layer extends from the first active region of the first row and across the cell boundary to the second active region of the second row.

17. An integrated circuit comprising:
an array of circuit cells arranged in a first row and at least a second row;
wherein gate regions and source/drain regions of the array of circuit cells are staggered at a cell boundary of the first row and the second row.

18. The integrated circuit of claim 17, further comprising individual gate contacts to at least one of the gate regions in the first row of the array of circuit cells and at least one of the gate regions in the second row of the array of circuit cells.

19. The integrated circuit of claim 17, further comprising a first gate contact to at least one of the gate regions in the first row of the array of circuit cells, a second gate contact to at least one of the gate regions in the second row of the array of circuit cells, and a gate connection layer connecting the first gate contact and the second gate contact, wherein the first gate contact, the second gate contact and the gate connection layer are formed at the cell boundary of the first row and the second row.

20. The integrated circuit of claim 17, further comprising a first gate contact to at least one of the gate regions in the first row of the array of circuit cells, a second gate contact to at least one of the gate regions in the second row of the array of circuit cells, and a gate connection layer connecting the first gate contact and the second gate contact, wherein the first gate contact is formed over a first active region of the first row, wherein the second gate contact is formed over a second active region of the second row, and wherein the gate connection layer extends from the first active region of the first row and across the cell boundary to the second active region of the second row.
